(19) United States
(12) Patent Application Publication
(10) Pub. No.: US 2008/0038538 A1
(43) Pub. Date: Feb. 14, 2008

(54) Method of Producing Nanostructure Tips

(76) Inventor: Brian Ruby, Seattle, WA (US)

Correspondence Address: Joseph P. Kincart, 8153 Middle Fork Way, Jacksonville, FL, 32256, US

(21) Appl. No.: 10/578,550

(22) PCT Filed: Nov. 5, 2004
(86) PCT No.: PCT/US04/36854

§ 371 Date: Jul. 6, 2007

Related U.S. Application Data
(60) Provisional application No. 60/518,384, filed on Nov. 6, 2003.

(51) Int. Cl. C23C 16/26; D01F 9/127

(52) U.S. Cl. 428/323; 427/331; 427/343; 427/458

(57) ABSTRACT

A method of producing a plurality of apparatuses having carbon nanotube tips includes providing a first substrate (100) having a first surface (102) with a plurality of precursor tips (202), providing a second substrate (300) having a second surface (302) facing the first surface (102), growing a carbon nanotube tip on substantially all of the precursor tips (202), and applying an electrical potential between the second surface (302) and ends of the carbon nanotubes that are distal to the precursor tips.

### CLAIM OF PRIORITY

This application claims priority under 35 USC §119(e) to U.S. patent application Ser. No. 60/518,384, filed on Nov. 6, 2003, the entire contents of which are hereby incorporated by reference.

### TECHNICAL FIELD

This invention relates to nanotubes, and more particularly to carbon nanotube AFM tips.

### BACKGROUND

Carbon nanotubes are carbon-based molecular structures, which can have diameters of a few nanometers and lengths of several nanometers to several micrometers. Carbon nanotubes have unique mechanical and electrical properties that make them useful for a variety of applications. For example, a carbon nantotube can be used as a probe tip in atomic force microscopy (AFM).

Atomic force microscopes use a probe tip to obtain images from a sample by dragging the probe tip over the surface of the specimen or within close proximity to the surface of the specimen. A probe tip that is attached to a cantilever can be dragged across the surface of the specimen and the displacement of the cantilever can be recorded as the probe tip tracks the topography of the specimen to generate an image of the sample. For example, a laser beam can be shined on the back surface of the cantilever while the probe tip is dragged across the surface of a sample, and the movement of the cantilever can be deduced from changes in the angle or position of a light beam that is reflected from the surface of the cantilever. The resolution of images produced by AFM is related to the size and shape of the probe tip, and tips with small diameters and high aspect ratios of their length to their diameter can be used to resolve small lateral and vertical features. Carbon nanotubes are useful as AFM probe tips because they are extremely strong, and can be made of various lengths and aspect ratios to suit the user's needs.

Carbon nanotubes have been produced for use as AFM tips, as described, for example, by Dai, et al. in U.S. Pat. No. 6,346,189 and in U.S. Patent Application Publication US2002/0178846, both of which are incorporated herein by reference. However, it has been difficult to mass produce such carbon nanotube tips.

### SUMMARY

In a first general aspect, a method of producing an apparatus with a carbon nanotube tip includes providing a first substrate having a first surface with a plurality of precursor tips, growing a carbon nanotube tip on substantially all of the precursor tips, and limiting the growth of substantially all of the carbon nanotube tips to a predetermined maximum length.

In another general aspect, a method of producing a plurality of apparatuses having carbon nanotube tips includes providing a first substrate having a first surface with a plurality of precursor tips, providing a second substrate having a second surface facing the first surface, growing a carbon nanotube tip on substantially all of the precursor tips, and applying an electrical potential between the second surface and ends of the carbon nanotubes that are distal to the precursor tips.

In a further general aspect, a method of producing an apparatus with a carbon nanotube atomic force microscopy tip includes providing a first substrate having a first surface with a plurality of cantilevers having a catalyst islands, growing a carbon nanotube tip on substantially all of the catalyst islands, and limiting the growth of substantially all of the carbon nanotube tips to a predetermined maximum length.

In another general aspect, a method of producing an apparatus with a nanostructure tip includes providing a first substrate having a first surface with a plurality of precursor tips, growing a nanostructure tip on substantially all of the precursor tips, and limiting the growth of substantially all of the nanostructure tips to a predetermined maximum length.

In another general aspect, a method of producing a plurality of apparatuses having nanostructure tips includes providing a first substrate having a first surface with a plurality of precursor tips, providing a second substrate having a second surface facing the first surface, growing a nanostructure tip on substantially all of the precursor tips, and applying an electrical potential between the second surface and ends of the nanostructures that are distal to the precursor tips.

In another general aspect, a method of producing an apparatus with a nanostructure atomic force microscopy tip includes providing a first substrate having a first surface with a plurality of cantilevers having a catalyst islands, growing a nanostructure tip on substantially all of the catalyst islands, and limiting the growth of substantially all of the nanostructure tips to a predetermined maximum length.

Implementations can include one or more of the following features. For example, a carbon nanotube tip can be separated from other carbon nanotube tips. The precursor tips can be supported on an atomic force microscopy cantilever. A second substrate having a second surface can be provided at a distance from and facing the first surface of the first substrate. The second substrate can be conductive, and an electrical potential can be applied between the second surface and ends of the carbon nanotubes that are distal to the precursor tips. Ends of the carbon nanotubes that are distal to the precursor tips can be cleaved from the second surface of the second substrate. The distance between the second surface and the first surface can be substantially constant or can vary.

The carbon nanotube tips can be shortened to a desired length. The desired length can be between about 5 nanometers and about 500 micrometers, between about 5 nanometers and about 50 micrometers, between about 5 nanometers and about 5 micrometers, between about 100 nanometers and about 500 micrometers, between about 100 nanometers and 50 micrometers, between about 100 nanometers and 5 micrometers, between about 500 nanometers and about 500 micrometers, between about 500 nanometers and 50 micrometers, between about 500 nanometers and 5 micrometers, or between about 3 micrometers and 5 micrometers.

In aspects involving the growth of nanostructures, implementations can include one or more of the following features. The nanostructures can be carbon nanostructures, cobalt oxide nanostructures, nanotubes, nanowires, or nanofibers. The nanostructure tips can be separated from other nanostructure tips. The precursor tips can be supported on an atomic force microscopy cantilever. A second substrate having a second surface can be provided at a distance from and facing the first surface of the first substrate. The second substrate can be conductive, and an electrical potential can be applied between the second surface and ends of the nanostructures that are distal to the precursor tips. Ends of the nanostructures that are distal to the precursor tips can be cleaved from the second surface of the second substrate. The distance between the second surface and the first surface can be substantially constant or can vary. The nanostructure tips can be shortened to a desired length.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a top view of a patterned substrate.

FIG. 2A is a side view of a portion of the patterned substrate showing an array of precursor tips.

FIG. 2B is a side view of a portion of the patterned substrate showing an array of precursor tips with a layer of resist.

FIG. 2C is a side view of a portion of the patterned substrate showing an array of precursor tips with a layer of catalytic material on top of the layer of resist.

FIG. 2D is a side view of a portion of the patterned substrate showing an array of precursor tips with the resist layer removed and catalytic material on the apexes of the precursor tips.

FIG. 3A is a top view of a flat, doped substrate with perimeter rails.

FIG. 3B is a side view of a sandwich of the patterned substrate and the doped substrate.

FIG. 4 is a schematic view of a processing furnace arrangement.

FIG. 5A and FIG. 5B are schematic side views of a portion of the patterned substrate showing an array of precursor tips.

FIGS. 6A and 6B are scanning electron micrograph images of a nanotube grown on a precursor tip.

Like reference symbols in the various drawings indicate like elements.

### DETAILED DESCRIPTION

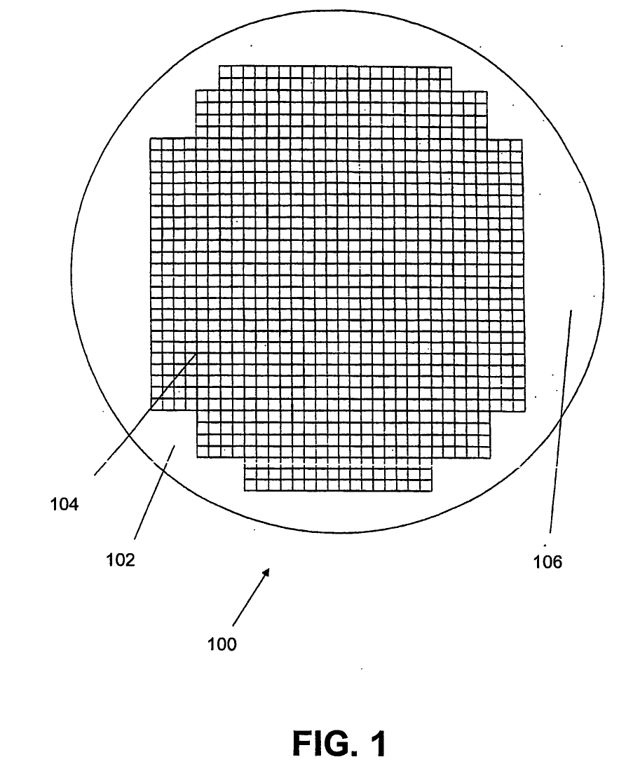

Referring to FIG. 1, a commercially available wafer substrate 100 (e.g., available from Nanodevices, Santa Barbara, Calif.) has a top surface 102 that includes an unpatterned perimeter 106 and a central patterned portion 104 with 375 prefabricated cantilevers with an pyramidal tip on each cantilever. The wafer substrate 100 can be made of silicon or other suitable materials for fabricating an array of cantilevers. The patterned wafer substrate 100 can be attached to a thicker substrate to provide support and flatness to the patterned wafer substrate 100 while chemical vapor deposition (CVD) steps are performed on the substrate 100.

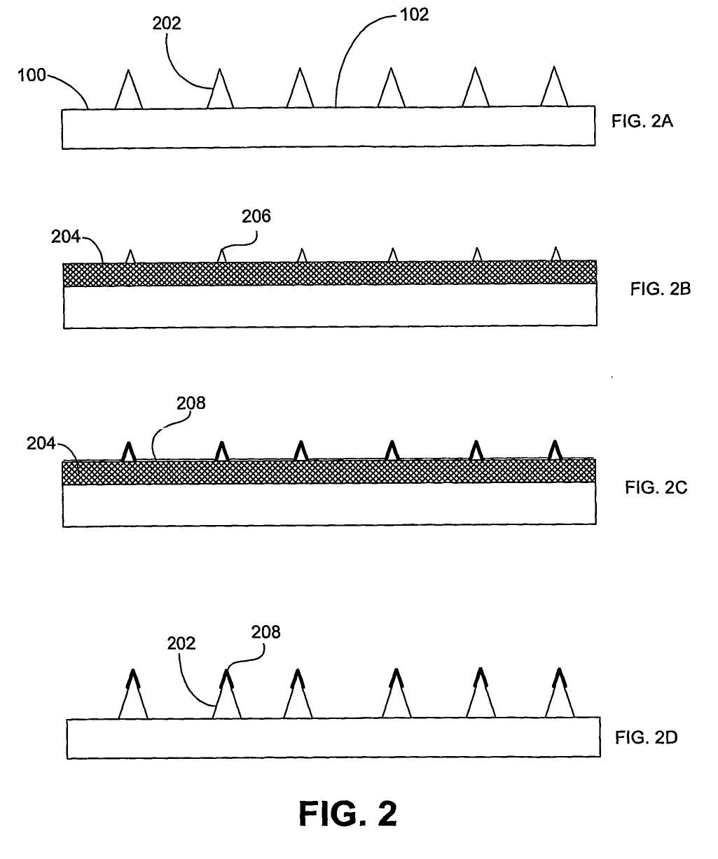

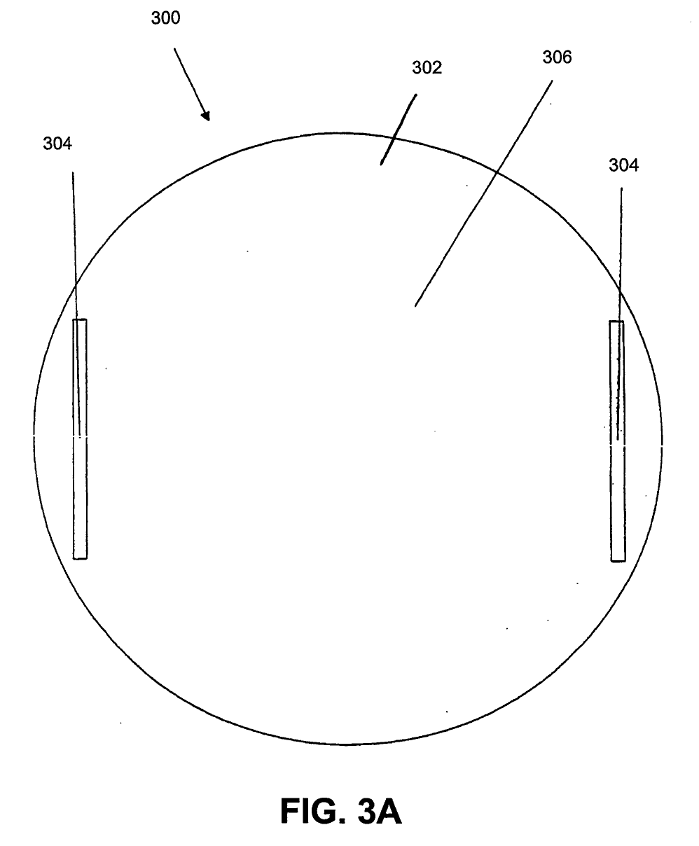

Referring to FIG. 2A, the pyramidal tips 202 can protrude about 1-20 microns above the top surface 102 of the substrate 100. On any given wafer substrate 100 the pyramidal tips 202 can have a uniform height to within about 5% of the specified average height of the pyramidal tips 202 on the substrate 100, however, different wafers from the same manufacturer can have pyramidal tips 202 with different average heights. The wafer surface 102 containing the array of pyramidal tips 202 is spin coated with a resist layer 204 to cover the surface 102 at the base of the pyramidal tips 202, as shown in FIG. 2B. A polymethlymethacrylate (PMMA) material is used for the resist layer 204, but other materials can also be used. The resist layer 204 tends to pool around the bases of the pyramidal tips 202, leaving the apexes of the pyramidal tips 202 uncoated by the resist layer. The resist can be applied to the top surface 102 several times to reach a desired thickness of the resist layer 204 that covers most of the pyramidal tips 202 but leaves the apexes 206 of the tips exposed. After an adequate amount of resist has been applied to cover all but the apexes 206 of the pyramidal tips 202, the resist is hardened by baking it on a hot plate at about 90° C. for about one minute.

Next, a catalyst suspension layer 208 is spin coated onto the apexes 206 of the pyramidal tips 202 and on top of the resist layer 204, as shown in FIG. 2C. The catalyst layer 208 contains materials that catalyze the growth of nanotubes on the apexes 206 of the tips 202. For example, catalyst suspension layer 208 containing Fe—Mo nanoparticles for catalyzing the growth of nanotubes can be prepared according to a procedure described in Li and Liu, “Preparation of Monodispersed Fe—Mo Nanoparticels as the Catalyst for CVD Synthesis of Carbon Nanotubes,” Chem. Matter, Vol. 13, pp. 1008-14 (2001), which is incorporated herein by reference. A catalyst suspension solution can be created by dissolving 1.00 mmol (0.196 g) Fe(CO)₅, 0.020 mmol (0.053 g) Mo(CO)₆, 0.100 mmol (0.144 g) octanoic acid and 0.100 mmol (0.242 g) bis-2-ethylhexylamine in 5.00 mL octyl ether and refluxing the solution under an N₂ atmosphere for 30 minutes at high temperature (e.g., about 300° C.). The formation of Fe—Mo catalytic nanoparticles in this solution is indicated by the solution turning black. Other catalytic materials can also be used. For example, a Co—Mo catalyst embedded in a silica matrix can be prepared according to a procedure described in “Long and Oriented Single-Walled Carbon Nanotubes Grown by Ethanol Chemical Vapor Deposition,” Limin Huang, Xiaodong Cui, Brian White, and Stephen P. O'Brien, J. Phys. Chem. B, vol. 108, pp. 16451-56 (2004) (hereinafter “Huang”), which is incorporated herein by reference.

In an alternative method, catalyst material can be applied to the entire surface 102 of the substrate 100 without first applying a resist layer. In such a case, the catalyst material is not limited to the apex 206 of a precursor tip 202, but is applied over the entire surface of the tip 202.

After the catalytic material solution is prepared according to Huang it is poured onto the central patterned portion 104. The first substrate 100 is pre-heated at 200° C. for 15 minutes so that when the catalyst solution is applied it evaporates very quickly, leaving the apexes 206 of the pyramidal tips 202 coated with a catalytic material 208, as shown in FIG. 2D. Because the pyramidal tips 202 provide a precursor base upon which nanotube tips are grown, the pyramidal tips 202 may also be known as precursor tips. The precursor tips 202 need not be pyramidal in shape but can be of any shape that provides a base upon which a catalytic material 208 may be deposited. The catalyst-coated apexes 206 are then calcinated according to the procedure described in Huang.

Although a method of applying catalyst material to the apexes 202 of precursor tips 202 has been described, catalyst material may be applied to localized islands at the end of individual cantilevers by other methods, and the presence of a precursor tip 202 is not necessary for locating catalyst material at the ends of the cantilevers. For example, known masking and lithography techniques can be used to deposit small catalyst islands directly onto the ends of flat cantilevers without using precursor tips 202 that protrude from the cantilevers.

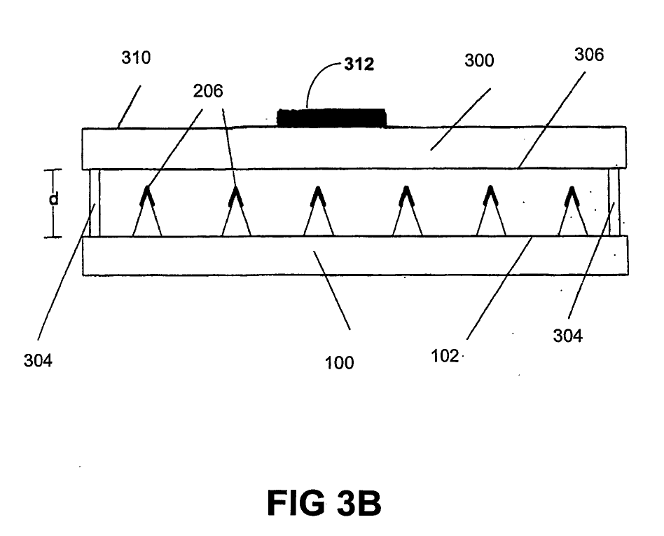

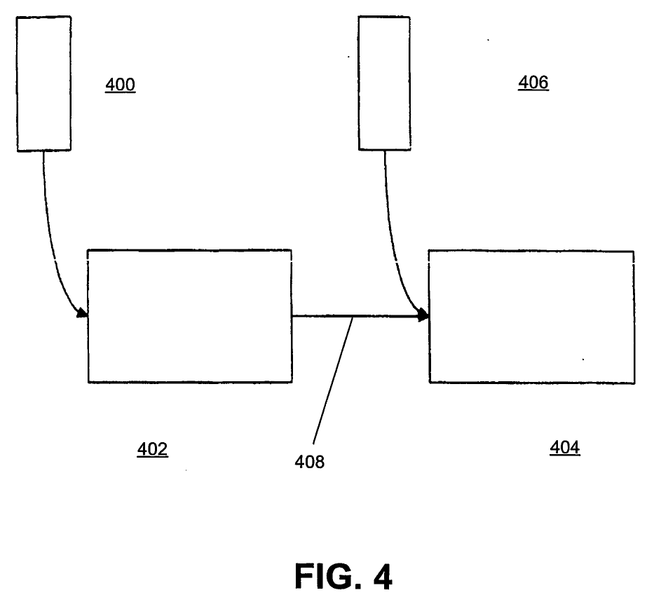

Referring to FIGS. 3A and 3B, a second substrate 300 having an etched top surface 302 with perimeter rails 304 that are higher than a central flat portion 306 can be placed over the first substrate 100 in a position that allows multiple nanotubes having predetermined lengths to be grown simultaneously on the apexes 206 of the precursor tips 202. The rails 304 of the second substrate 300 can be of equal height or they can be different heights. The rails can be created on a flat, doped silicon substrate 300 by well-known lithography and etching techniques. For example, lithography and etching techniques can be used to remove a layer from the surface of the substrate except in the regions of the rails 304, which are not etched, such that rails 304 that extend above the surface 306 of the substrate 300 remain after the etching process. Referring to FIG. 3B, when the second substrate 300 is placed on top of the patterned wafer 100, the perimeter rails 304 rest on the perimeter 106 of the patterned wafer 100 so that the central flat portion 306 of the second substrate 300 is disposed at a distance, d, from the top surface 102 of the patterned wafer 100 to form a sandwich having a hollow central tunnel between the patterned wafer 100 and the second wafer 300. Although FIG. 3B shows the precursor tips 202 facing up, the orientation of the first wafer 100 and the second wafer 300 can be reversed, such that the first wafer 100 is above the second wafer 300 and the precursor tips 202 face down. A layer of conductive and material can be deposited on the surface 306 of the second wafer 300 to enhance the conductivity of the wafer when used to shorten the nanotubes grown on the precursor tips 202, as described in more detail below. For example, a conductive material as described in Maruyama et al., “Direct Synthesis of High-Quality Single-Walled Carbon Nanotubes on Silicon and Quartz Substrates,” Chem. Phys. Lett., Vol. 377, p. 49-54, which is incorporated herein by reference, can be applied to the surface 306 of the wafer. The layer of conductive material can also include catalytic material for catalyzing the growth of nanotubes on the surface or for attracting nanotubes grown on the precursor tips 202 to grow directly towards the surface 306.

Nanotubes can be grown on the apexes 206 of the precursor tips 202 by flowing carbon-containing gasses through the hollow central tunnel and over the apexes 206. In the tunnel between the patterned wafer 100 and the second wafer 300, the apexes 206 are located at a distance from the central flat portion 306 of the second substrate 300, where the distance between the central flat portion 306 and the apexes 206 of the precursor tips 202 is equal to the distance, d, minus the height of the precursor tips 202. When the rails 304 are of equal height, this distance is substantially constant across the entire surface of the flat portion 306. When the rails are of different heights, the distance varies across the central flat portion 306. The distance between the apexes 206 of the precursor tips 202 and the surface 306 of the doped substrate 300 determines the maximum length to which nanotubes can grow on the precursor tips 202. This maximum length can be chosen to be between 5 nanometers and 500 micrometers. The second substrate 300 can be made of doped silicon (e.g., doped with 10¹⁷ boron atoms per cm³) so that the substrate 300 is conductive. An electrical contact 312 can be disposed on a back surface 310 of the second substrate 300, such that an electrical potential can be applied to the substrate 300.

After the wafer sandwich is constructed, a carbon-containing gas is flowed through the central tunnel to grow nanotubes on the apexes 206 of the precursor tips 202 through a CVD process. Referring to FIG. 4, as described in Zheng, et al., “Efficient CVD Growth of Single-Walled Carbon Nanotubes on Surfaces Using Carbon Monoxide Precursor,” Nano Lett., Vol. 2, pp. 895-898 (2002), which is incorporated herein by reference, in one process for growing the nanotubes, a two furnace arrangement can be used. The wafer sandwich is positioned in a second furnace 404, and H₂ is input from a first gas source 400 at a rate of 400 standard cubic centimeters per minute (SCCM) into a first furnace 402 until the first furnace reaches a temperature of about 500° C., while H₂ is input from a second gas source 406 at a rate of 400 SCCM into a second furnace 404 until the second furnace reaches a temperature of about 800-900° C. The first furnace 402 and the second furnace 404 are coupled by a small conduit 408, such that gas can flow from one furnace to the other. When both furnaces 402 and 404 reach their intended temperatures, the gas flow into the first furnace 402 is changed to CO at a rate of 400 SCCM, and the flow of H₂ into the second furnace 404 is increased to 800 SCCM. While CO flows through the central tunnel of the wafer sandwich and over the surface 102 of the patterned wafer, CO is dissociated and carbon nanotubes grow on the catalyst covered apexes 206 of the precursor tips 202. Nanotubes grow on the precursor tips 202 perpendicular to the surface 102 of the wafer until they reach the flat central portion 306 of the second wafer 300. These gas flows are maintained for about 15 minutes and then the entire system is cooled under a flow of H₂. Growth of nanotubes on the catalyst islands at the apexes 206 of the precursor tips progresses until the nanotubes reach their maximum length near to or in contact with the surface 306 of the doped silicon wafer 300.

Although a two furnace setup using CO as a source of carbon can be used to grow nanotubes, nanotubes can be grown using other methods as well. For example, a single furnace can be used with methane as the source of carbon, as decribed by Dai in U.S. Pat. No. 6,346,189, which is incorporated herein by reference. In another process, the wafer sandwich can be loaded into a single furnace chamber, whereupon argon and hydrogen gas is flowed through the furnace over the wafer sandwich at flow rates of 480 and 100 SCCM, respectively. The temperature of the wafer sandwich is raised to about 850° C. while the argon and hydrogen gas is introduced to the chamber to reduce catalyst material from an oxide form to a metallic form. After the furnace temperature reaches about 850° C., the argon and hydrogen gas flows are maintained for about 10 minutes, and then ethanol is introduced to the furnace at a flow rate of about 10 SCCM, while the hydrogen flow rate is reduced to about 40 SCCM and the argon flow rate is increased to about 740 SCCM. The ethanol, argon, hydrogen mixtures is flowed into the furnace for about 15 minutes, and the carbon in the ethanol gas provides the source of carbon for the nanotubes to grow on the apexes 206 of the tips 202. After nanotubes have been grown, the ethanol and hydrogen gas flows are terminated and the furnace is cooled to room temperature under an argon gas flow. After the nanotubes have been grown on the apexes 206 of the precursor tips 202 and the system has been cooled, the nanotubes grown on the apexes are shortened to desired lengths. In one process, after the growth furnace(s) has cooled, the furnace containing the wafer sandwich is flushed with a non-reactive gas (e.g., Ar, He, Xe, Kr, N₂) to remove impurities. Then, a constant voltage is applied to the doped wafer 300, while the first wafer 100 is held at ground. The potential difference between the wafers 100 and 300 can be about 1.5 volts or can be higher, for example, about 20-50 volts. The application of the voltage to the doped wafer 300 breaks connections between the nanotubes and the surface 306 of the doped wafer 300 and cleaves the ends of the nanotubes that are distal from the precursor tips from the surface of the second substrate. As the voltage is ramped up, the nanotubes are shortened. The nanotubes grown on the precursor tips 202 are all shortened at the same time, such that their free ends become located at substantially the same distance from the surface 306 of the doped wafer 300. In addition to cleaving and shortening by the application of a voltage, the nanotube tips can be shortened and cleaved in other ways, for example, by the application of a liquid or a gas phase chemical, which causes cleaving or shortening of the nanotubes.

After the nanotubes have been shortened, the individual cantilevers on the patterned wafer 100 can be separated from each other and used in individual atomic force microscopes.

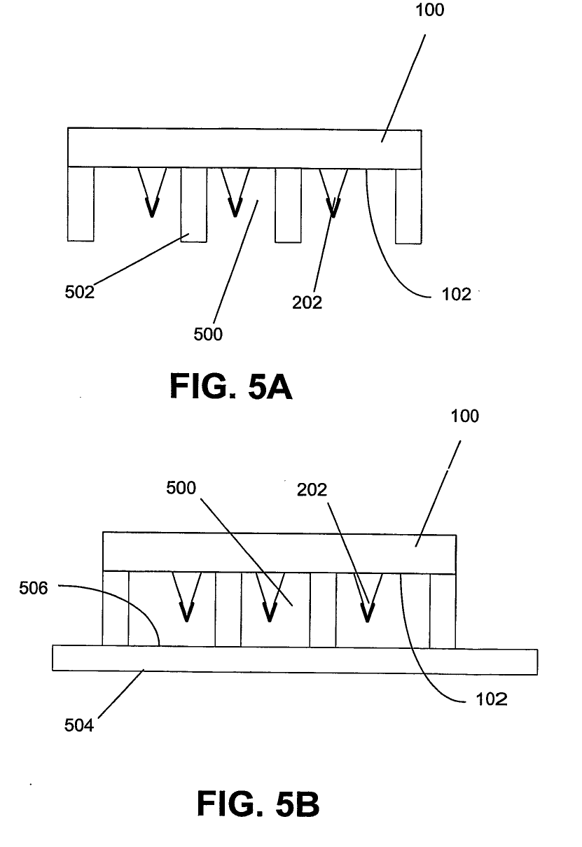

Referring to FIG. 5A, as an alternative to the precursor tips 202 protruding above the surface 102 of the substrate 100, the precursor tips 202 can be located in between rails 502 that are created on the surface of the substrate 100. The rails 502 can be crated by etching the surface of the substrate 100, such that the precursor tips 202 are formed in channels 500 between the rails 502, which protect the tip 202 from damage. Referring to FIG. 5B, to form nanotubes on the precursor tips 202 located between rails 502, a flat substrate 504 having a surface 506 is placed on top of the rails 502, and carbon-containing gas is flowed through the channels 500 to deliver material for nanotube growth on the precursor tips 202. The length of nanotubes grown on a precursor tip 202 in such a configuration depends on the distance between the apex of the tip 202 and the surface 506 of the substrate 504.

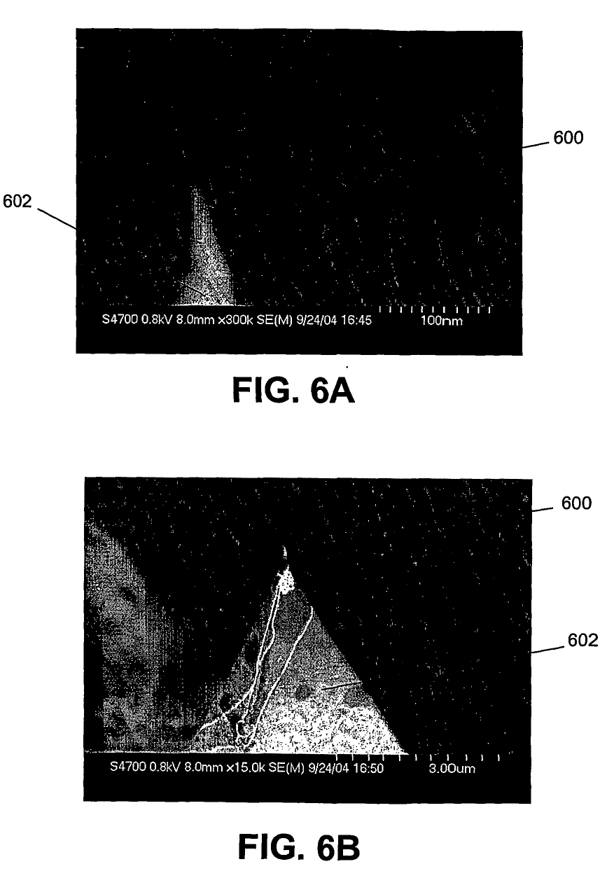

Referring to FIGS. 6A and 6B, nanotubes 600 grown on precursor tips 602 with the above described methods are shown in scanning electron micrograph images.

Although growth of uniform length carbon nanotubes has been described, the methods and systems described herein can be used to grow other uniform length nanostructures (i.e., nanotubes, nanowires, nanofibers) of other chemical compositions as well. For example, uniform length cobalt oxide (Co₃O₄) wires can be grown.

### OTHER EMBODIMENTS

A number of embodiments of the invention have been described. Nevertheless, it will be understood that various modifications may be made. Accordingly, other embodiments are within the scope of the following claims.

1-73. (canceled)

74. A method of simultaneously producing multiple nanostructures of a predetermined length, the method comprising:
coating at least a portion of multiple tips formed on a first substrate with a catalyst, wherein each respective tip comprises a base and an apex;
positioning a first surface of a second substrate distal to the multiple tips, wherein the distance of the first surface of the second substrate from the multiple tips correlates with the maximum predetermined length of the multiple nanostructures; and
forming the multiple nanostructures between the respective apexes of the tips and the surface of the second substrate.

75. The method of claim 74 wherein the nanostructure comprises a carbon nanotube.

76. The method of claim 74 wherein the portion of a tip coated with the catalyst comprises the base of the tip.

77. The method of claim 74 wherein the portion of a tip coated with the catalyst comprises the apex of the tip.

78. The method of claim 74 wherein the nanostructures are formed by additional steps comprising:
flowing a carbon containing gas over the catalyst coated apexes to grow carbon nanotubes protruding from the multiple catalyst coated tips until further growth is limited by the second substrate; and
flushing an area between the first substrate and the second substrate with a nonreactive gas.

79. The method of claim 74 wherein the first surface of the second substrate positioned distal to the multiple tips comprises a conductive material.

80. The method of claim 74 additionally comprising the step of applying a voltage differential between the second substrate and the multiple tips which is operative to shorten the length of the respective carbon nanotubes grown on the multiple tips.

81. The method of claim 74 additionally comprising the step of applying a voltage differential between the first surface of the second substrate and a second surface of the second substrate, wherein the voltage application is operative to cleave two or more of the carbon nanotubes from the second substrate.

82. The method of claim 74 additionally comprising the step of applying a voltage differential between the second substrate and the multiple tips which is operative to cleave two or more of the carbon nanotubes from the second substrate and shorten the length of the respective carbon nanotubes grown on the multiple tips, wherein the voltage comprises between 0.5 and 50 volts.

83. The method of claim 74 additionally comprising the step of:
applying a liquid phase chemical to cleave the carbon nanotubes from the second substrate and shorten the cleaved nanotubes.

84. The method of claim 74 additionally comprising the step of:
applying a gas phase chemical to cleave the carbon nanotubes from the second substrate and shorten the cleaved nanotubes.

85. The method of claim 74 additionally comprising the steps of flowing a carbon containing gas over the catalyst coated apexes comprises:
placing the first substrate combined with the second substrate into a furnace;
heating the furnace until the furnace reaches a temperature of at least about 750° C.;
flowing gas into the furnace wherein the gas comprises one of: H₂, CO, ethanol and methane.

86. The method of claim 85 wherein the gas is flowed into the furnace for a period of about 15 minutes or less.

87. The method of claim 85 additionally comprising the steps of:
cooling the furnace to about room temperature; and
flowing argon into the furnace while it is cooled to about room temperature.

88. An apparatus of nanostructures, the apparatus comprising:
a first substrate comprising a surface comprising multiple tips, each respective tip comprising a base and an apex;
a nanostructure having a proximate end and a distal end, the proximate end extending from each respective tip;
a second substrate comprising a surface, wherein the distance of the surface from each respective tip correlates with the distal end of essentially each nanostructure.

89. The apparatus of claim 88 the proximate end extends essentially perpendicular from each respective apex.

90. The apparatus of claim 88 wherein each nanostructure comprises a carbon nanotube.

91. The apparatus of claim 88 wherein each apex points essentially away from the first substrate at an angle of about 90°.

92. The apparatus of claim 91 wherein the surface of the first substrate is essentially parallel to the second substrate and the maximum length of each carbon nanotube correlates with the distance of the surface from the respective tips.

93. The apparatus of claim 88 additionally comprising a coating on at least a portion of each tip, the coating comprising at least one of: a catalyst; a transition metal and a transition metal oxide.
